(19) United States
(12) Patent Application Publication
(10) Pub. No.: US 2021/0123871 A1
(43) Pub. Date: Apr. 29, 2021

(54) Resonant Sensor Integrated with Active Amplifier Chip

(71) Applicant: Shanghai University, Shanghai (CN)

(72) Inventors: Yongjin Zhou, Shanghai (CN); Qiaoyu Li, Shanghai (CN)

(21) Appl. No.: 17/078,166

(22) Filed: Oct. 23, 2020

(30) Foreign Application Priority Data
Oct. 23, 2019 (CN) 201911010238.1

(51) Int. Cl. G01N 22/00

(52) U.S. Cl. CPC G01N 22/00

(57) ABSTRACT

The disclosure provides a resonant sensor integrated with an active amplifier chip. The sensor includes: a first metal dielectric layer, an air-like dielectric layer, a second metal dielectric layer, and an excitation layer. The excitation layer is sequentially covered with the second metal dielectric layer, the air-like dielectric layer, and the first metal dielectric layer. The first metal dielectric layer includes an active amplifier chip. Based on the disclosure, the resolution and the sensitivity of the sensor can be improved.

### TECHNICAL FIELD

The disclosure relates to the field of active sensing, and in particular, to a resonant sensor integrated with an active amplifier chip.

### BACKGROUND

Since characteristics of various biochemical reagents and substances generally need to be measured and distinguished during biological and chemical scientific research, an efficient, accurate, powerful, and low-cost biochemical reagent detection method is essential for biological and chemical scientific research. Therefore, more and more technologies are used for improving performance of sensors for accurate measurement of reagents. Because microwave sensors have the advantages of easy operations, high sensitivity, and being non-contact, application of the microwave sensors has become a new research hotspot. The dielectric constant of a substance has a specific relationship with its physical property of interest. The microwave sensor infers the dielectric constant and the physical property of the substance by measuring the scattering parameters. Through near-field coupling between the substance to be measured and the sensor based on a microwave resonator, a traditional microwave sensor determines a change in the dielectric constant so as to determine a change in a property of the substance, based on a change in a resonance position and in resonance amplitude. However, the open resonator usually has the radiation loss in a microwave band, resulting in a decrease in a quality factor (Q) of the sensor based on the microwave resonator, especially when the material to be measured has a large loss, which accelerates deterioration of the quality factor (Q). Although the quality factor (Q) value of the microwave sensor is increased by using a technical means in a manner of passive control in most cases, for example, optimizing a unit structure to obtain a better electromagnetic characteristic, passive control is not dynamic and flexible, so that an application range of a passive sensor is limited. Fano resonance can decrease the radiation loss. However, during measurement, the sensor based on Fano resonance cannot obtain both a high quality factor and strong resonance intensity. Consequently, the resolution and sensitivity of a traditional sensor are often limited.

### SUMMARY

The disclosure aims to provide a resonant sensor integrated with an active amplifier chip, to increase the resolution and the sensitivity of the sensor.

To achieve the above objective, the disclosure provides the following solutions:

A resonant sensor integrated with an active amplifier chip, including a first metal dielectric layer, an air-like dielectric layer, a second metal dielectric layer, and an excitation layer, where the excitation layer is sequentially covered with the second metal dielectric layer, the air-like dielectric layer, and the first metal dielectric layer, and the first metal dielectric layer includes an active amplifier chip.

Optionally, the first metal dielectric layer includes a first metal grating structure layer and a first dielectric plate, the active amplifier chip is located on the first metal grating structure layer, and the first dielectric plate is covered with the first metal grating structure layer.

Optionally, the first metal dielectric layer further includes a capacitor, the capacitor is located on the first metal grating structure layer, and the capacitor is configured to isolate a direct current.

Optionally, the first metal dielectric layer further includes a grounding metal patch, and the grounding metal patch is located between the active amplifier chip and the first metal grating structure layer.

Optionally, the second metal dielectric layer includes a second metal grating structure layer and a second dielectric plate, the second dielectric plate is covered with the second metal grating structure layer, and the second metal grating structure layer is covered with the air-like dielectric layer.

Optionally, the excitation layer includes a microstrip line, a third dielectric plate, and a metal backplane, the metal backplane is covered with the third dielectric plate, the microstrip line is located between the third dielectric plate and the second dielectric plate, and the microstrip line is used to connected to an external excitation source.

Optionally, the sensor further includes a plurality of through-holes, each of the through-holes passes through the first dielectric plate, the air-like dielectric layer, the second dielectric plate, the third dielectric plate, and the metal backplane, one metal rod is inserted into each of the through-holes, and each metal rod is used to ensure that the active amplifier chip is grounded.

Optionally, a surface of each of the first metal grating structure layer and the second metal grating structure layer is etched with a periodic groove.

Optionally, a thickness of each of the first dielectric plate, the second dielectric plate, the third dielectric plate, and the air-like dielectric layer is adjustable.

According to specific examples provided in the disclosure, the disclosure provides the following technical effects:

The disclosure provides a resonant sensor integrated with an active amplifier chip. Radiation losses may be effectively reduced by using two resonant structures: a first metal dielectric layer and a second metal dielectric layer. The active amplifier chip may be introduced to compensate for a metal loss, a dielectric loss, and a loss caused by a sample to be measured, thereby greatly improving a quality factor and resonance intensity of the resonant sensor. Compared with a passive resonator structure, the quality factor of the resonant sensor may be increased by 57 times, and the resonance intensity may be increased by 1.88 times.

### BRIEF DESCRIPTION OF THE DRAWINGS

In order to illustrate the examples of the disclosure or the technical solutions of the prior art, the accompanying drawing to be used will be described briefly below. Notably, the following accompanying drawing merely illustrates some examples of the disclosure, but other accompanying drawings can also be obtained those of ordinary skill in the art based on the accompanying drawing without any creative efforts.

FIG. 1 is a composition diagram of a resonant sensor integrated with an active amplifier chip according to the disclosure;

FIG. 2 is a specific structural diagram of a resonant sensor integrated with an active amplifier chip according to the disclosure;

FIG. 3 is a top view of a first metal dielectric layer according to the disclosure;

FIG. 4 is a top view of an air-like dielectric layer according to the disclosure;

FIG. 5 is a top view of a second metal dielectric layer according to the disclosure;

FIG. 6 is a structural diagram of using a microstrip line as an interface according to the disclosure;

FIG. 7 is a comparison diagram of transmission coefficients of a resonant sensor integrated with an active amplifier chip and a single-layer resonant sensor covered with a grooved metal plate according to the disclosure;

FIG. 8 is a comparison diagram of transmission coefficients of a resonant sensor integrated with an active amplifier chip and a grooved metal plate to which no active amplifier chip is loaded according to the disclosure.

### DETAILED DESCRIPTION

The following clearly and completely describes the technical solutions in the examples of the disclosure with reference to accompanying drawings in the examples of the disclosure. Apparently, the described examples are merely a part rather than all of the examples of the disclosure. All other examples obtained by a person of ordinary skill in the art based on the examples of the disclosure without creative efforts shall fall within the protection scope of the disclosure.

An objective of the disclosure is to provide a resonant sensor integrated with an active amplifier chip, to increase the resolution and the sensitivity of the sensor.

To make the foregoing objective, features, and advantages of the disclosure clearer and more comprehensible, the disclosure is further described in detail below with reference to the accompanying drawings and specific examples.

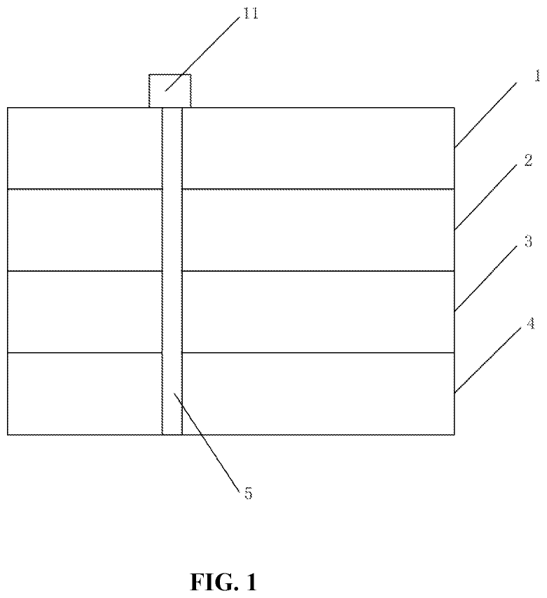

FIG. 1 is a composition diagram of a resonant sensor integrated with an active amplifier chip according to the disclosure. As shown in FIG. 1, a resonant sensor integrated with an active amplifier chip is provided, including a first metal dielectric layer 1, an air-like dielectric layer 2, a second metal dielectric layer 3, and an excitation layer 4. The excitation layer 4 is sequentially covered with the second metal dielectric layer 3, the air-like dielectric layer 2, and the first metal dielectric layer 1. The first metal dielectric layer 1 includes an active amplifier chip 11. The first metal dielectric layer 1 and the second metal dielectric layer 3 form two resonant structures.

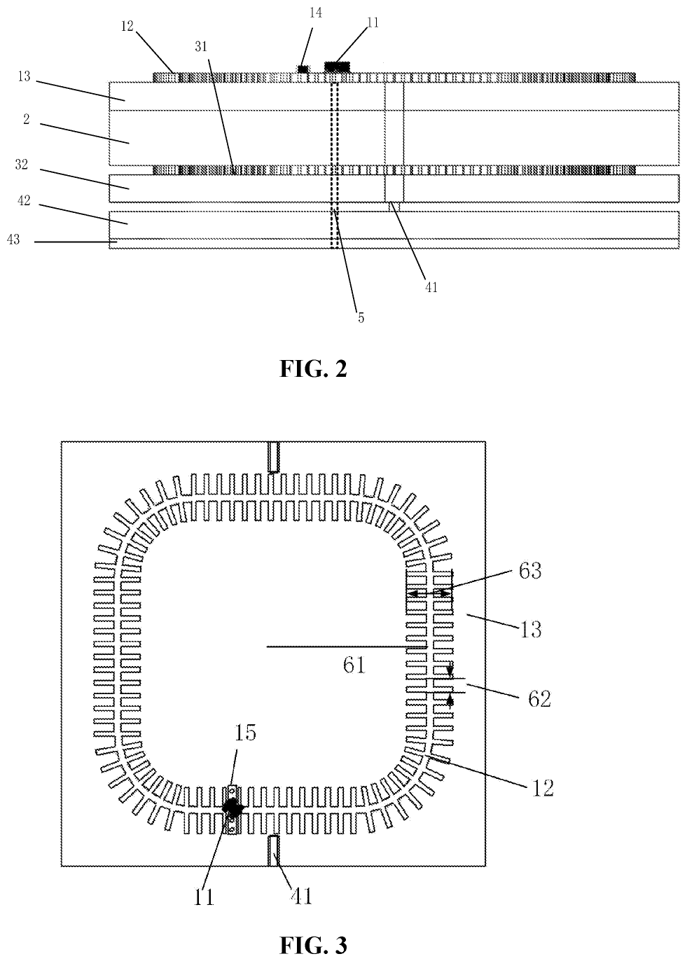

FIG. 2 is a specific structural diagram of a resonant sensor integrated with an active amplifier chip according to the disclosure. As shown in FIG. 2, the first metal dielectric layer 1 includes an active amplifier chip 11, a first metal grating structure layer 12, and a first dielectric plate 13. The active amplifier chip is 11 is located on the first metal grating structure layer 12, and the first dielectric plate 13 is covered with the first metal grating structure layer 12. To place the active amplifier chip 11, the first metal grating structure layer 12 is provided with an opening groove, to ensure that the active amplifier chip 11 can be smoothly grounded. The first metal dielectric layer 1 further includes a capacitor 14, the capacitor 14 is located on the first metal grating structure layer 12, and the capacitor 14 is configured to isolate a direct current. The first metal dielectric layer 1 further includes a grounding metal patch 15, and the grounding metal patch 15 is located between the active amplifier chip 11 and the first metal grating structure layer 12. The active amplifier chip 11 includes four pins: one input pin, one output pin, and two grounding pins. The grounding metal patch 15 is connected to the two grounding pins. As shown in FIG. 2, the second metal dielectric layer 3 includes a second metal grating structure layer 31 and a second dielectric plate 32, the second dielectric plate 32 is covered with the second metal grating structure layer 31, and the second metal grating structure layer 31 is covered with the air-like dielectric layer 2. As shown in FIG. 2, the excitation layer 4 includes a microstrip line 41, a third dielectric plate 42, and a metal backplane 43. The metal backplane 43 is covered with the third dielectric plate 42. The microstrip line 41 is located between the third dielectric plate 42 and second dielectric plate 32, and the microstrip line 41 is used to connect to an external excitation source. There are two microstrip line excitation ports in the disclosure, one is used as an input end, and the other is used as an output end. As shown in FIG. 2, the sensor further includes a plurality of through-holes 5, each of the through-holes passes through the first dielectric plate 13, the air-like dielectric layer 2, the second dielectric plate 32, the third dielectric plate 42, and the metal backplane 43, one metal rod is inserted into each of the through-holes, and each metal rod is used to ensure that the active amplifier chip 11 is grounded.

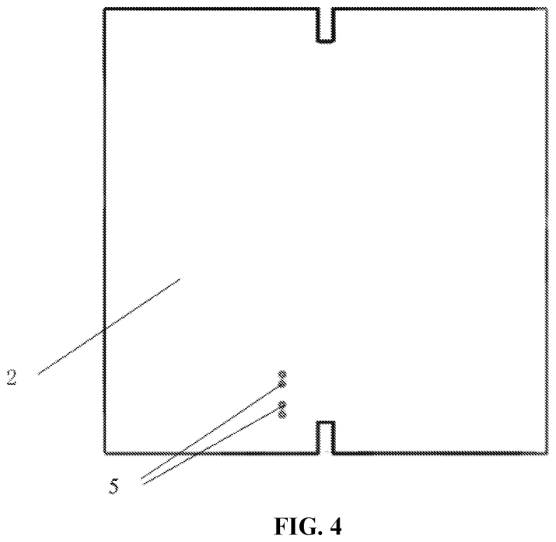

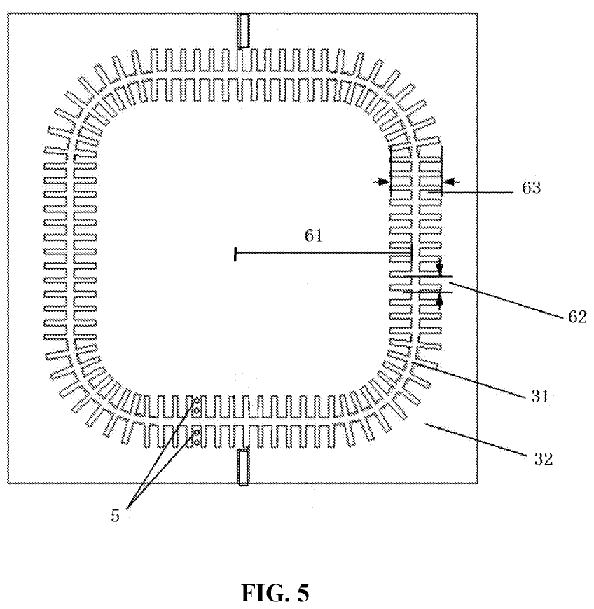

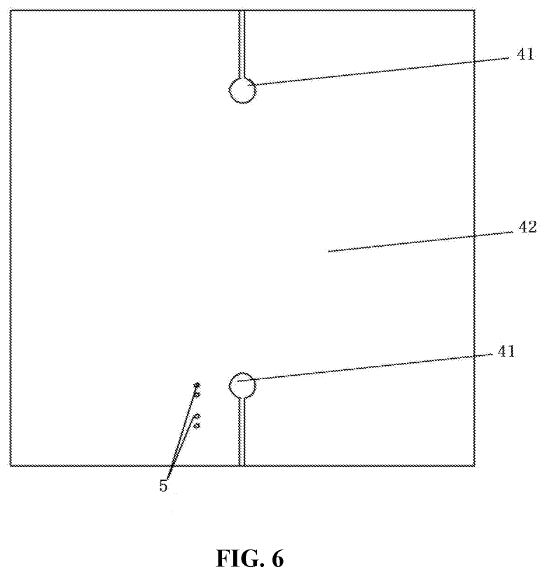

FIG. 3 is a top view of a first metal dielectric layer according to the disclosure. FIG. 4 is a top view of an air-like dielectric layer according to the disclosure. FIG. 5 is a top view of a second metal dielectric layer according to the disclosure. FIG. 6 is a structural diagram of using a microstrip line as an interface according to the disclosure.

A thickness of each of the first metal grating structure layer 12 and the second metal grating structure layer 31 is very small, and is preferably 0.035 mm in the disclosure.

A surface of each of the first metal grating structure layer 12 and the second metal grating structure layer 31 is etched with a periodic groove. Compared with a ring structure without a metal grating groove, such a grating structure has a stronger electromagnetic wave restraint capability and has a miniaturization advantage when radius slits of metal rings are the same. A resonance mode generated through coupling by the first metal grating structure layer 12 and the second metal grating structure layer 31 whose surfaces are etched with a periodic groove has two resonance points: a resonance peak and a resonance valley, which have stronger resonance intensity and a higher quality factor than the Lorentzian resonance mode. In the disclosure, the first metal dielectric layer 1 and the second metal dielectric layer 3 cooperate to excite a required resonance. A single-layer dielectric layer covered with metal cannot excite the required resonance.

A thickness of each of the first dielectric plate 13, the second dielectric plate 32, the third dielectric plate 42, and the air-like dielectric layer 2 is adjustable. Geometric parameters of a grooved metal ring width 61, a distance 62 between two metal grooves, and a radius slit 63 of a metal ring etched with a periodic groove can all be adjusted.

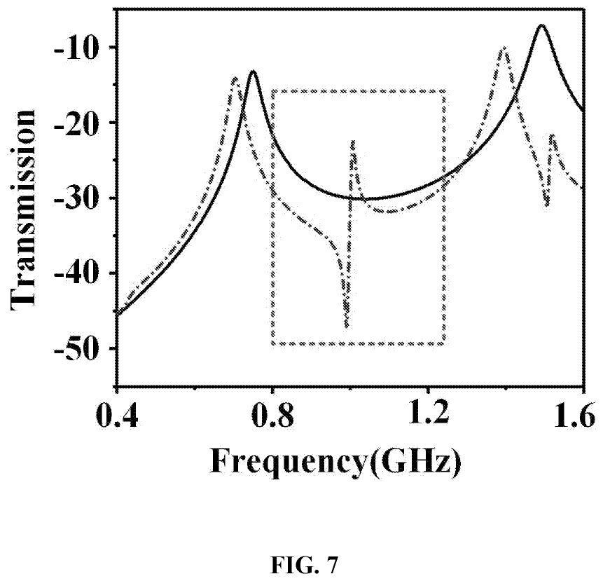

FIG. 7 is a comparison diagram of transmission coefficients of a resonant sensor integrated with an active amplifier chip and a single-layer resonant sensor covered with a grooved metal plate according to the disclosure. As shown in FIG. 7, a resonance mode generated through coupling by the first metal grating structure layer and the second metal grating structure layer whose surfaces are etched with a periodic groove has two resonance points: a resonance peak and a resonance valley.

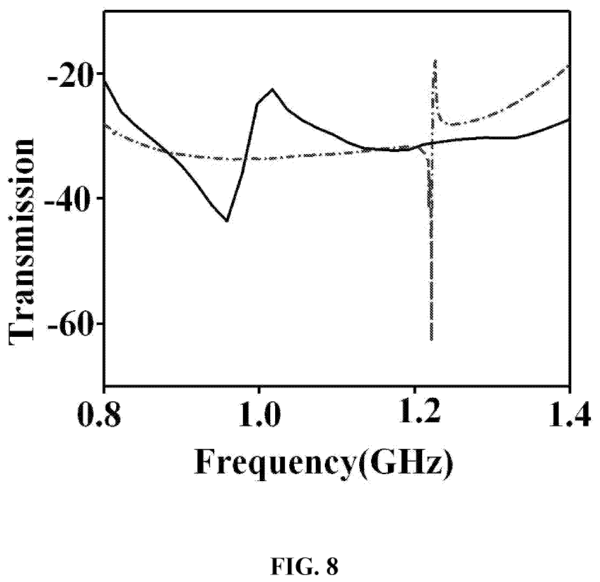

FIG. 8 is a comparison diagram of transmission coefficients of a resonant sensor integrated with an active amplifier chip and a grooved metal plate to which no active amplifier chip is loaded according to the disclosure. As shown in FIG. 8, it can be seen that compared with a passive resonator structure without an active amplifier chip, a quality factor and resonance intensity of the structure to which the active amplifier chip is introduced are greatly improved. The quality factor of the passive resonator is around 49, and the resonance intensity is 19.84 dB. After the active amplifier chip is introduced, an optimized quality factor can reach 2802 with an increase of up to 57 times, and the resonance intensity is 37.42 dB. It can be seen that the disclosure makes effects of increasing the quality factor and resonance intensity.

The structure in the disclosure is processed by using a printed circuit board technology. According to different working frequency bands, different processing technologies can be further used for processing, such as a wire cut electrical discharge machining technology or a photoetching technology.

Each example of the present specification is described in a progressive manner, each example focuses on the difference from other examples, and the same and similar parts between the examples may refer to each other.

Several examples are used for illustration of the principles and implementation methods of the disclosure. The description of the examples is used to help illustrate the apparatus and its core concept in the disclosure. In addition, those of ordinary skill in the art can make various modifications in terms of specific implementation methods and scope of application in accordance with the concept of the disclosure. In conclusion, the content of this specification shall not be construed as a limitation to the disclosure.

1. A resonant sensor integrated with an active amplifier chip, comprising a first metal dielectric layer, an air-like dielectric layer, a second metal dielectric layer, and an excitation layer, wherein the excitation layer is sequentially covered with the second metal dielectric layer, the air-like dielectric layer, and the first metal dielectric layer, and the first metal dielectric layer comprises an active amplifier chip.

2. The resonant sensor integrated with an active amplifier chip according to claim 1, wherein the first metal dielectric layer comprises a first metal grating structure layer and a first dielectric plate, the active amplifier chip is located on the first metal grating structure layer, and the first dielectric plate is covered with the first metal grating structure layer.

3. The resonant sensor integrated with an active amplifier chip according to claim 2, wherein the first metal dielectric layer further comprises a capacitor, the capacitor is located on the first metal grating structure layer, and the capacitor is configured to isolate a direct current.

4. The resonant sensor integrated with an active amplifier chip according to claim 2, wherein the first metal dielectric layer further comprises a grounding metal patch, and the grounding metal patch is located between the active amplifier chip and the first metal grating structure layer.

5. The resonant sensor integrated with an active amplifier chip according to claim 4, wherein the second metal dielectric layer comprises a second metal grating structure layer and a second dielectric plate, the second dielectric plate is covered with the second metal grating structure layer, and the second metal grating structure layer is covered with the air-like dielectric layer.

6. The resonant sensor integrated with an active amplifier chip according to claim 5, wherein the excitation layer comprises a microstrip line, a third dielectric plate, and a metal backplane, the metal backplane is covered with the third dielectric plate, the microstrip line is located between the third dielectric plate and the second dielectric plate, and the microstrip line is used to connected to an external excitation source.

7. The resonant sensor integrated with an active amplifier chip according to claim 6, wherein the sensor further comprises a plurality of through-holes, each of the through-holes passes through the first dielectric plate, the air-like dielectric layer, the second dielectric plate, the third dielectric plate, and the metal backplane, one metal rod is inserted into each of the through-holes, and each metal rod is used to ensure that the active amplifier chip is grounded.

8. The resonant sensor integrated with an active amplifier chip according to claim 7, wherein a surface of each of the first metal grating structure layer and the second metal grating structure layer is etched with a periodic groove.

9. The resonant sensor integrated with an active amplifier chip according to claim 7, wherein a thickness of each of the first dielectric plate, the second dielectric plate, the third dielectric plate, and the air-like dielectric layer is adjustable.
